(19) United States
(12) Patent Application Publication
(10) Pub. No.: US 2010/0101485 A1
(43) Pub. Date: Apr. 29, 2010

(54) Manufacturing method of silicon single crystal

(75) Inventors: Senlin Fu, Niigata (JP); Toshio Hisaichi, Hiigata (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Covalent Materials Corporation, Tokyo (JP)

(21) Appl. No.: 12/588,391

(22) Filed: Oct. 14, 2009

(30) Foreign Application Priority Data
Oct. 23, 2008 (JP) 2008-272732

(51) Int. Cl. C30B 15/22

(52) U.S. Cl. 117/32

(57) ABSTRACT

In appropriate setting of magnetic field applied to a molten silicon 12 stored in a cylindrical quartz crucible 11, the maximum value B₀ of magnetic flux density on a vertical symmetric axis 17 as a cylindrical axis of the quartz crucible 11 in horizontal magnetic field generated by a pair of exciting coils 13 and 14 calls B₀. On circle at which horizontally symmetric plane 18 traversing and perpendicular to a vertically symmetric axis 17 becoming magnetic flux B₀ crosses an inner diameter of the quartz crucible 11, the minimum value of magnetic flux density calls Bₘᵢₙ, and the maximum value of magnetic flux density calls Bₘₐₓ. Those magnetic flux densities B₀, Bₘᵢₙ and Bₘₐₓ are adjusted to be given ranges, and upward flow and temperature of a molten silicon 12 at the lower part of a solid-liquid interface 15a are appropriately controlled.

### BACKGROUND OF THE INVENTION

1. Field of the Invention

The present invention relates to a silicon single crystal growth technique by MCZ method (Magnetic field applied CZochralski method). More particularly, the present invention relates to a manufacturing method of silicon single crystal having a large diameter, such as 300 mm or more.

2. Description of Related Art

Many silicon single crystals used as a silicon wafer in a substrate of a semiconductor device are grown by a pulling out method so-called a CZ method. Currently, a silicon single crystal ingot grown by this method has a diameter of about 300 mm (12 inches), and further increasing the diameter (for example, 450 mm (18 inches)) is investigated.

In the CZ method, a cylindrical quartz crucible with bottom placed in a growth furnace is filled with raw material silicon (generally polycrystal silicon), and the silicon is heated with a heater to form molten silicon. Seed crystal is attached to the surface of the melt, and using the seed crystal as growth nuclei, the molten silicon is grown into silicon crystals by pulling out the seed crystal in a given rate while solidifying the molten silicon. In pulling out the silicon singly crystal, the quartz crucible is rotated around a rotation axis which is the same as a pulling out direction in a given rate. Thus pulled out single crystal ingot is formed into a thin disc-shaped silicon wafer by performing through various processing such as slicing and mirror polishing.

In a semiconductor device using the silicon wafer as a substrate, high integration and high performance proceed owing to nanofabrication of its semiconductor element. The semiconductor requires, for example, gettering function of getting metal impurities which deteriorates performance of the device and high grade crystal having reduced crystal defects due to point defects such as atomic vacancy and interstitial silicon. Further, the semiconductor requires enlargement of its diameter which increases the yield of chips of a semiconductor device and makes easy to reduce costs in manufacturing devices.

To meet the above described demands, in recent years, the conventional CZ method is developed and a so-called MCZ method is widely used such that single crystal is grown while applying magnetic field to the melt. HMCZ method (Horizontal MCZ method), VMCZ method (Vertical MCZ method) and CMCZ (Cusp MCZ method) are heretofore developed as the MCZ method. Of those methods, at present the utility of the HMCZ method and the CMCZ method is experimentally clarified, and those two methods are put into practical use.

In the MCZ method, magnets are arranged at an outer wall part of a growth furnace and appropriate magnetic field is applied to molten silicon. The magnetic field effectively suppresses natural convection flow due to heat of conductive molten silicon stored in a quartz crucible.

The magnetic field suppress oxygen eluted in the molten silicon from an inner wall surface of the quartz crucible from reaching a solid-liquid interface of silicon single crystal, and as a result, a concentration of solid solution oxygen in the silicon single crystal is controlled.

In the pulling out growth by the MCZ method, various investigations to improve uniformity of oxygen concentration in the pulling out direction or a radial direction in the silicon single crystal have been made by trial and error together with other pulling out conditions such as rotation of a crucible and rotation of crystal (for example, see Japanese Patent Examined Publication JP-B-2546736 and Japanese Patent Unexamined Publication JP-A-2000-264785).

Nowadays, as for the enlargement of diameter of the silicon wafer, many investigations in pulling out a silicon single crystal for a wafer of which diameter is 450 mm (about 18 inches) (next generation), 675 mm (about 27 inches) (next-next generation) are proceeding. In the formation of such a silicon single crystal having large diameter, increase in natural convection flow in a molten silicon in a large-sized quartz crucible, decrease in pulling out rate and increase in time of feedback control become substantially physical factors which make more difficult to put the same to practical use. For the formation of a silicon single crystal having a large diameter, there is high possibility that the MCZ method is essential to suppress the natural convection flow and achieve stabilization of temperature of molten silicon in a quartz crucible.

Further, when the MCZ method is applied for production of high grade crystal having reduced crystal defects caused by point defects, control of a so-called V (pulling out rate)/G (temperature gradient in direction of crystal axis) ratio, control of shape of solid-liquid interface, and the like become important. If the control is not sufficient, it becomes difficult to reduce defects such as dislocation cluster defects and octagonal void defects caused by interstitial silicon or atomic vacancy, or defect of ring-shaped OSF (Oxidation induced Sacking Fault) generated on a wafer surface. Alternatively, practical use of a so-called Neutral crystal in which interstitial silicon or atomic vacancy more than heat equilibrium is not present in single crystal at the pulling out becomes difficult.

### SUMMARY OF THE INVENTION

In the growth of silicon single crystal by the MCZ method, many technical investigations are heretofore mainly made from the standpoint of improving uniformity of oxygen concentration in silicon single crystal. However, technical investigations from the standpoints of flow control and temperature control of the molten silicon in a quartz crucible are few. The reason is that it is extremely difficult at present to clarify the relationship among intensity of magnetic flux density in molten silicon or its intensity distribution, the melt flow and temperature distribution based on accurate actual measurement.

Although the MCZ method is superior to the CZ method in controlling concentration of oxygen due to the suppression of the convection flow of the molten silicon, it is difficult to make temperature gradient between solid-liquid interface of silicon single crystal and interior of a quartz crucible. Furthermore, where convection flow is suppressed by strong magnetic field, surface temperature of the molten silicon is greatly decreased. As a result, dislocation of silicon single crystal due to concentration of heat stress is easily generated at the growth of a neck portion and a shoulder portion in pulling out the silicon single crystal.

However, in a field of pulling out growth by the MCZ method, heretofore, there are not any comprehensively helpful analysis regarding application of magnetic field applied to the molten silicon, flow and temperature of molten silicon in a quartz crucible. Further, regarding the current level of the manufacturing technique for further enlargement of the diameter of the silicon single crystal, it is difficult to appropriately design magnetic field for solving the above problems and putting high grade crystal growth to practical use.

The present invention has been made in view of the above circumstances, and an object thereof is to provide a manufacturing method of a silicon single crystal which gives guidelines for designing appropriate magnetic field and enables to appropriately set magnetic field in molten silicon.

The present inventors have conducted parameter fitting of analysis program to results under many experimental conditions in pulling out of silicon single crystal using analysis program of solid-solution interface-linked three-dimensional molten convection flow, oxygen analysis program, heat transfer analysis program and the like. Precisions of analysis of flow and temperature of molten silicon, analysis of oxygen behaviors and the like are improved, and high precision experiment prediction could be made. Throughout the improvement of the precisions, the present inventors have found an optimization method of magnetic field in the pulling out growth by MCZ method applying horizontal magnetic field. The present invention is based on the finding obtained from those investigations.

Accordingly, to achieve the above objects, according to an aspect of the invention, there is provided a manufacturing method of silicon single crystal, including:

pulling out a silicon single crystal from melt silicon stored in a cylindrical crucible by Czochralski method while applying horizontal magnetic field satisfying formulas of

2000/(Φcry/Φcru)^{1/2}−2000≦B₀≦2000/(Φcry/Φcru)^{1/2}+2000 and

0.8B₀≦Bₘᵢₙ or 0.6Bₘₐₓ≦Bₘᵢₙ

wherein B₀ [gauss] is a maximum value of a magnetic flux density on an cylindrical axis of the crucible,

Bₘᵢₙ [gauss] is a minimum value of the magnetic flux density on a circle where an inner diameter of the crucible intersects with a horizontal plane which crosses a point of which magnetic flux density is B₀ and is perpendicular to the cylindrical axis of the crucible,

Bₘₐₓ [gauss] is a maximum value of the magnetic flux density on the circle,

Φ_{cry} is a diameter of a straight body part of the silicon single crystal,

Φ_{cru} is an inner diameter of the crucible, and

the horizontal magnetic field is applied by a pair of exciting coils disposed on both side portions of the crucible.

According to still another aspect of the invention, there is provided a manufacturing method of a silicon single crystal including:

pulling out a silicon single crystal from melt silicon stored in a cylindrical crucible by Czochralski method while applying horizontal magnetic field satisfying formulas of

1500/(Φcry/Φcru)−2000≦B₀≦1500/(Φcry/Φcru)+2000 and

Bₘᵢₙ≦0.9B₀ or Bₘᵢₙ≦0.65Bₘₐₓ

wherein B₀ [gauss] is a maximum value of a magnetic flux density on an cylindrical axis of the crucible,

Bₘᵢₙ [gauss] is a minimum value of the magnetic flux density on a circle where an inner diameter of the crucible intersects with a horizontal plane which crosses a point of which magnetic flux density is B₀ and is perpendicular to the cylindrical axis of the crucible,

Bₘₐₓ [gauss] is a maximum value of the magnetic flux density on the circle,

Φcry is a diameter of a straight body part of the silicon single crystal,

Φcru is an inner diameter of the crucible, and

the horizontal magnetic field is applied by a pair of exciting coils disposed on both side portions of the crucible.

### BRIEF DESCRIPTION OF THE DRAWINGS

FIG. 1 is a schematic view showing the state of the growth by pulling out of silicon single crystal for explaining the first exemplary embodiment of the present invention;

FIG. 2 is an explanatory view schematically showing circular exciting coils in the first exemplary embodiment of the present invention;

FIG. 3 is an explanatory view schematically showing saddle-shaped exciting coils in the first exemplary embodiment of the present invention;

FIG. 4 shows a magnetic flux density distribution of one example of I-type horizontal magnetic field generated by circular exciting coils in the first exemplary embodiment of the present invention;

FIG. 5 shows a magnetic flux density distribution of one example of II-type horizontal magnetic field generated by saddle-shaped exciting coils in the first exemplary embodiment of the present invention;

FIG. 6 shows a correlation of the optimum range of magnetic flux density in the I-type horizontal magnetic field in the first exemplary embodiment of the present invention;

FIG. 7 shows a correlation of the optimum range of magnetic flux density in the II-type horizontal magnetic field in the first exemplary embodiment of the present invention;

FIG. 8 shows a magnetic flux density distribution showing one example of magnetic field intensity deviation in a horizontal symmetric plane of the I-type and II-type horizontal magnetic fields in the first exemplary embodiment of the present invention;

FIG. 9 is a graph showing suppression effect to oscillating flow of molten silicon in the first exemplary embodiment of the present invention;

FIG. 10 is a graph showing homogenization effect of oxygen concentration distribution in the first exemplary embodiment of the present invention;

FIG. 11 is a graph showing one example of free surface temperature of molten silicon for explaining suppression effect of crystal deformation in the first exemplary embodiment of the present invention;

FIGS. 12A and 12B are schematic views showing a pulling out state for explaining crystal deformation in the first exemplary embodiment of the present invention;

FIG. 13 is a graph showing homogenization effect of G (temperature gradient in a direction of crystal axis) at the solid-liquid interface of the first exemplary embodiment of the present invention;

FIG. 14 is a schematic vertically sectional view of a manufacturing apparatus of silicon single crystal for carrying out a manufacturing method of silicon single crystal in the second exemplary embodiment of the present invention;

FIG. 15 is a correlation view for explaining oxygen concentration control in the growth of silicon single crystal using I-type horizontal magnetic field in the second exemplary embodiment of the present invention;

FIG. 16 is a correlation view for explaining oxygen concentration control in the growth of silicon single crystal using II-type horizontal magnetic field in the second exemplary embodiment of the present invention;

### DETAILED DESCRIPTION OF EXEMPLARY EMBODIMENTS OF THE PRESENT INVENTION

Exemplary embodiments of the present invention are described below by referring to the drawings. In the drawings, the same or similar parts have the common reference numerals and signs, and the overlapped descriptions are partially omitted.

### First Exemplary Embodiment

An optimization method of horizontal magnetic field in pulling out silicon single crystal according to a first exemplary embodiment of the present invention is described below.

In the growth of silicon single crystal, a molten silicon 12 is stored in a bottomed cylindrical quartz crucible 11, and transverse magnetic field (referred to “horizontal magnetic field”) is applied to the molten silicon 12 from a pair of exciting coils 13 and 14 arranged sides portions of the quartz crucible 11 so as to face each other. Silicon crystal 15 is pulled up and grown in the order of a neck part in a so-called dash-necking process using a seed crystal 16 as a nucleus, a shoulder part increasing a diameter to the desired crystal diameter, a straight body part having a constant diameter and a tail part which decreases a diameter.

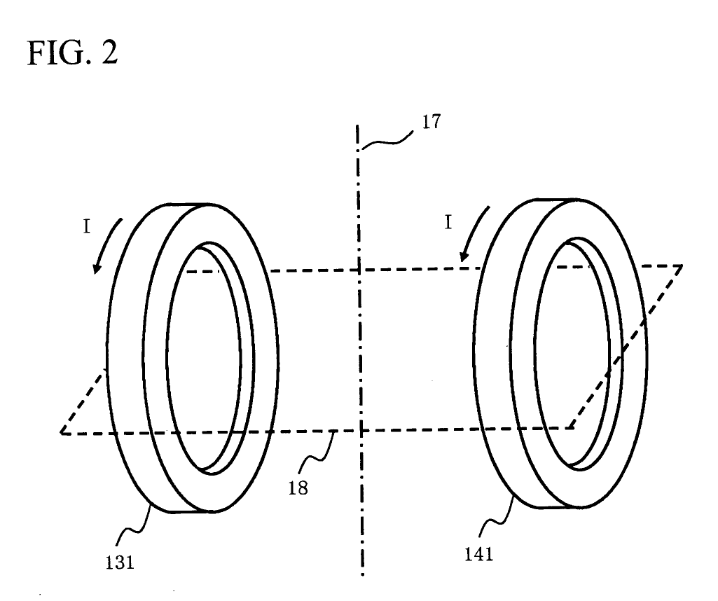

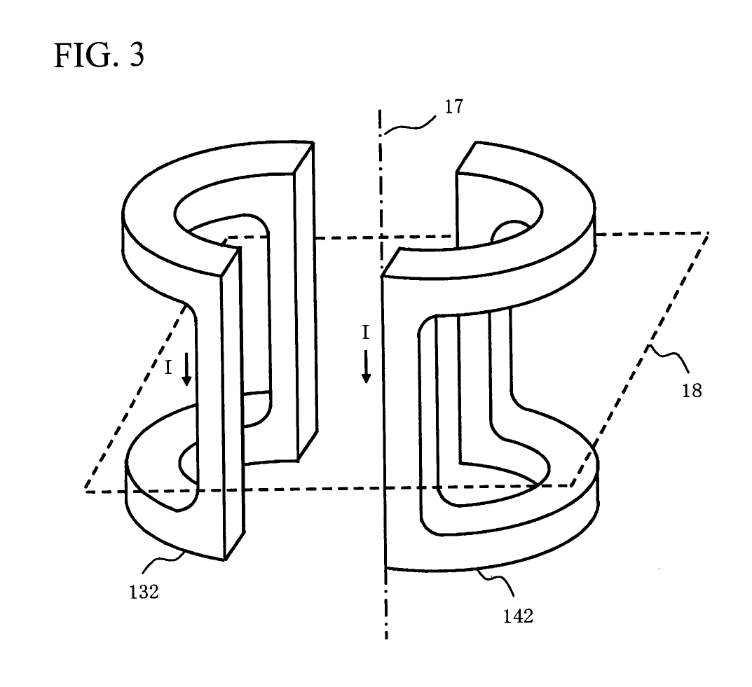

The exciting coils 13 and 14 are a pair of circular exciting coils 131 and 141 having the same shape and size arranged so as to face with each other as shown in FIG. 2, or a pair of saddle-shaped exciting coils 132 and 142 having the same shape and size arranged so as to face with each other as shown in FIG. 3. Those exciting coils may be wound several times, or may be either of an iron-core coil or an iron-coreless Helmholz type magnetic field coil. Horizontal magnetic field generated by the pair of the circular exciting coils or the pair of the saddle-shaped exciting coils are called U-shaped transverse magnetic field or saddle-shaped transverse magnetic field, respectively.

In the pulling out growth in which the horizontal magnetic field is applied, a vertical symmetric axis 17 which is a cylindrical (central) axis of the quartz crucible 11 is the same direction as a direction of a crystal axis of the silicon single crystal 15, and is generally nearly consistent with a central axis of pulling out direction of the silicon single crystal 15.

When the maximum value of magnetic flux density vector B on the vertical symmetric axis 17 is B₀ [gauss], a horizontal symmetric plane 18 is a horizontal plane which passes a position of the maximum value B₀ on the cylindrical axis and is perpendicular to the vertical symmetric axis 17. Here, the horizontal symmetric plane 18 is positioned on a solid-liquid interface 15a between the molten silicon 12 and the silicon single crystal 15 or slightly lower than the solid-liquid interface 15a.

The maximum value of the magnetic flux density vector B on a circle at which the horizontal symmetric plane 18 intersects with an inner diameter of the quartz crucible is defined as Bₘₐₓ [gauss], and its minimum value is defined as Bₘᵢₙ [gauss].

For example, when direct-current electricity I is flown to the circular exciting coils 131 and 141, in which superconductor or normal conductor is wound in nearly circle shape, from the respective electrodes (not shown) in the same direction, the horizontal symmetric plane 18 is a symmetric plane of magnetic field generated by the electricity I, and is a plane at which a component of a direction perpendicular to the plane is zero.

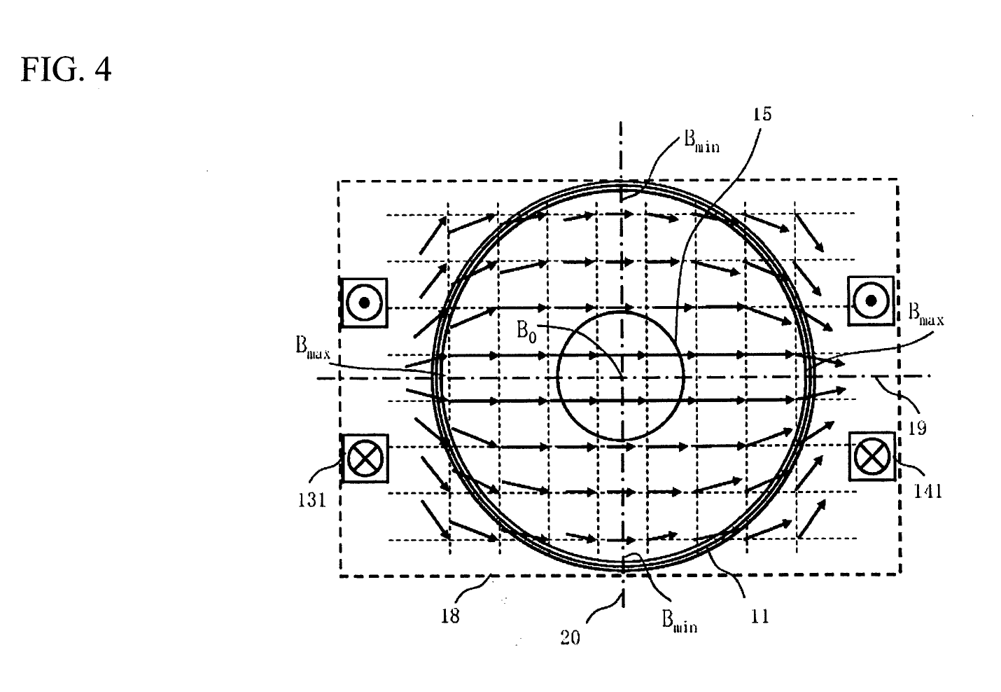

One example of magnetic flux density vector B distribution on the horizontal symmetric plane 18 is shown in FIG. 4. As shown in FIG. 4, the magnetic flux density vector B is present on the horizontal symmetric plane 18, and is distributed toward the circular exciting coil 141 from the circular exciting coil 131. Note that another magnetic flux density vector B located upward or downward relative to the horizontal symmetric plane 18 has a component perpendicular to the horizontal symmetric plane 18.

In FIG. 4, the magnetic flux density vector B on the horizontal symmetric plane 18 has the maximum value B₀ on cylindrical axis which is located on a central position of the quartz crucible 11. Furthermore, as shown in FIG. 4, the magnetic flux density vector B has the maximum value Bₘₐₓ at two points where the inner diameter of the quartz crucible 15 intersects with a horizontal line 19 which connects centers of circles of the circular exciting coils 131 and 141.

On the other hand, the magnetic flux density vector B has the minimum value Bₘᵢₙ at points where the inner diameter of the quartz crucible 15 intersects with a vertical line 20 which passes the central position of the quartz crucible 11 and is perpendicular to the horizontal line 19.

However, FIG. 4 is one example showing the case that the circular exciting coils 131 and 141 are perfect circles having the same shape and size, and if those shapes or size differ, the positions of the maximum value Bₘₐₓ and the minimum value Bₘᵢₙ differ from the above-described positions.

Similarly, in the case that direct-current electricity I is applied from the respective electrodes (not shown) to the saddle-shaped exciting coils 132 and 142 of superconductor or normal conductor in the same direction as shown in FIG. 3, the horizontal symmetric plane 18 is defined as a symmetric plane of magnetic field generated by the electricity I, and as a plane at which a component perpendicular to the plane is zero.

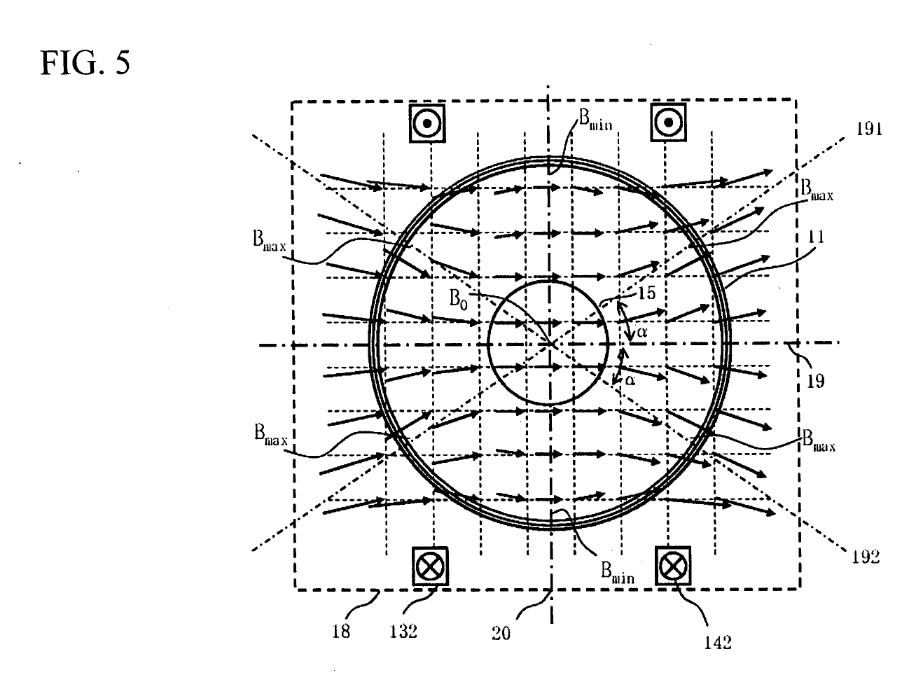

One example of the magnetic flux density vector B distribution on the horizontal symmetric plane 18 is shown in FIG. 5. As shown in FIG. 5, the magnetic flux density vector B is present on the horizontal symmetric plane 18, and is distributed toward the saddle-shaped exciting coil 142 from the saddle-shaped exciting coil 132. In this case, similar to the case of FIG. 4, the magnetic flux density vector B on the horizontal symmetric plane 18 has the maximum value B0 on cylindrical axis which is the central position of the quartz crucible 11.

Two oblique lines 191 and 192 intersect with the horizontal line 19 connecting centers of the saddle-shaped exciting coils 132 and 142 with oblique angle α, respectively. The magnetic flux density vector B has the maximum value Bₘₐₓ at four contact points where the inner diameter of the quartz crucible 15 intersects with the two oblique lines 191 and 192. Here, the oblique angle α depends on a shape of the saddle-shaped exciting coil. Depending on the shape of the saddle-shaped exciting coil, the oblique angles of the oblique line 191 and 192 relative to the horizontal line 19 may differ with each other.

Further, the magnetic flux density vector B has the minimum value Bₘᵢₙ at two points where the inner diameter of the quartz crucible 15 intersects with a vertical line 20 which passes the central position of the quartz crucible 11 and is perpendicular to the horizontal line 19.

However, FIG. 5 is one example showing the case that the saddle-shaped exciting coils 132 and 142 have the same shape and size, and where those shapes or size differ, the positions of the maximum value Bₘₐₓ and the minimum value Bₘᵢₙ differ from the above-described positions.

In view of the above analysis, an optimized horizontal magnetic field is obtained by setting the maximum value B₀ on cylindrical axis generated in the molten silicon 12 in the quartz crucible 11 by the exciting coils 13 and 14 so as to satisfy following formula (1).

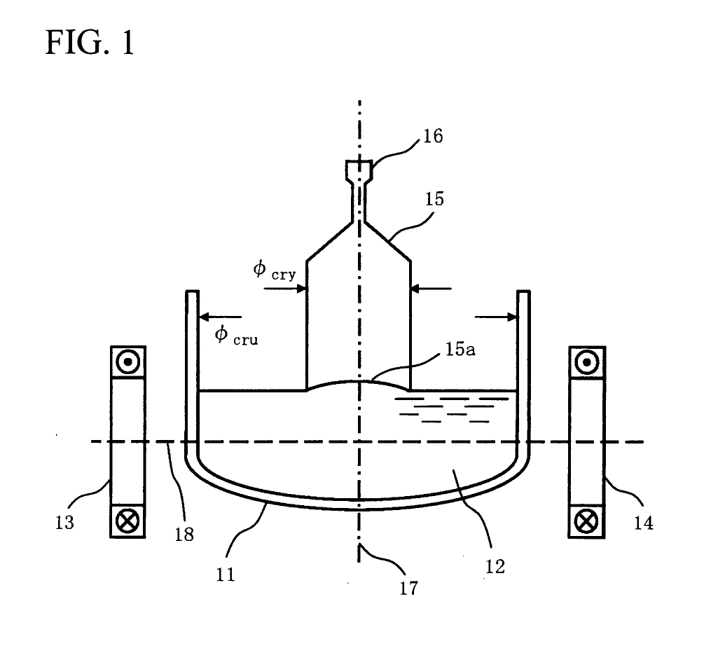

1500/(Φcry/Φcru)−2000≦B₀≦1500(Φcry/Φcru)+2000 (1)

wherein Φ_{cry} is a diameter of a straight body part of the silicon single crystal 15 and Φ_{cru} is the inner diameter of the quartz crucible 11, as shown in FIG. 1.

The formula (1) is preferred to the case where the minimum value Bₘᵢₙ on the horizontal symmetric plane 18 is satisfied with Bₘᵢₙ≦0.65Bₘₐₓ (hereinafter referred to “I-type horizontal magnetic field”) and the exciting coils 13 and 14 is the circular exciting coils 131 and 141.

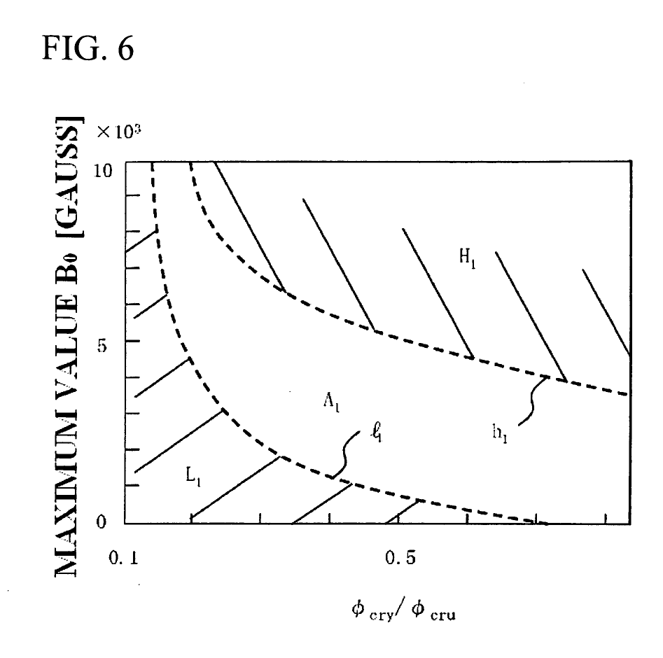

The formula (1) is explained below by referring to FIG. 6. FIG. 6 is a correlation diagram showing the relationship of the maximum value B₀ on cylindrical axis and (Φ_{cry}/Φ_{cru}). The vertical axis is the maximum value B₀ on cylindrical axis and the horizontal axis is (Φ_{cry}/Φ_{cru}). In this case, the I-type horizontal magnetic field is generated by the circular exciting coils.

In FIG. 6, a region H₁ indicates a condition which may cause crystal deformation. The generation of crystal deformation means that a diameter of a straight body part of the silicon single crystal 15 periodically fluctuates in a pulling out direction, or scatter of crystal habit line of crystal is generated. Those crystal deformations are observed with CCD camera and the like. Further, if the deformation is large, induced is freeze phenomenon in which molten silicon is solidified by contacting with a part of an inner wall of a quartz crucible.

In FIG. 6, a broken line h₁ is the lower limit curve of the region H₁, and is obtained by numeric analysis using analysis program of solid-solution interface-linked three-dimensional convection flow, oxygen analysis program and heat transfer analysis program, as described before. The lower limit curve is consistent with the measurement result of the crystal deformation, and the broken line h₁ is satisfied with following formula (5).

B₀=1500/(Φcry/Φcru)+2000 (5)

In FIG. 6, a region L₁ indicates a condition which may cause oscillating flow of molten silicon. The generation of oscillating flow of molten silicon means generation of rotating flow or generation of side flow, due to turbulent flow of a molten silicon in the lower region of the solid-liquid interface 15a. Those generations are measured with X-ray observation of so-called tracer particles of molten silicon flow.

In FIG. 6, a broken line l₁ is the upper limit curve of the region L₁, and is obtained by numeric analysis using analysis program of solid-solution interface-linked three-dimensional convection flow, oxygen analysis program and heat transfer analysis program, as described before. The upper limit curve is consistent with the measurement result of the crystal deformation, and the broken line l₁ is satisfied with following formula (6).

B₀=1500/(Φcry/Φcru)−2000 (6)

As described above, the formula (1) shows an appropriate region A₁ (shown in FIG. 6) of a horizontal magnetic field on which crystal deformation is not generated and oscillating flow of molten silicon is not generated.

The optimization of the I-type horizontal magnetic field is preferably conducted such that the maximum value B₀ on cylindrical axis generated in the molten silicon 12 in the quartz crucible 11 by the exciting coils 13 and 14 is satisfied with following formula (2).

1500(ΦcryΦcru)−1000≦B₀≦1500/(Φcry/Φcru)+1000 (2)

Alternatively, optimization of other horizontal magnetic field is conducted such that the maximum value B₀ on cylindrical axis generated in the molten silicon 12 in the quartz crucible 11 by the exciting coils 13 and 14 is satisfied with following formula (3).

2000/(Φcry/Φcru)^{1/2}−2000≦B₀≦2000/(Φcry/Φcru)^{1/2}+2000 (3)

The formula (5) is preferred to the case that the minimum value Bₘᵢₙ on the horizontal symmetric plane 18 is satisfied with 0.8B₀≦Bₘᵢₙ or 0.6Bₘₐₓ≦Bₘᵢₙ (hereinafter referred to “II-type horizontal magnetic field”) and the exciting coils 13 and 14 comprise is the saddle-shaped exciting coils 132 and 142.

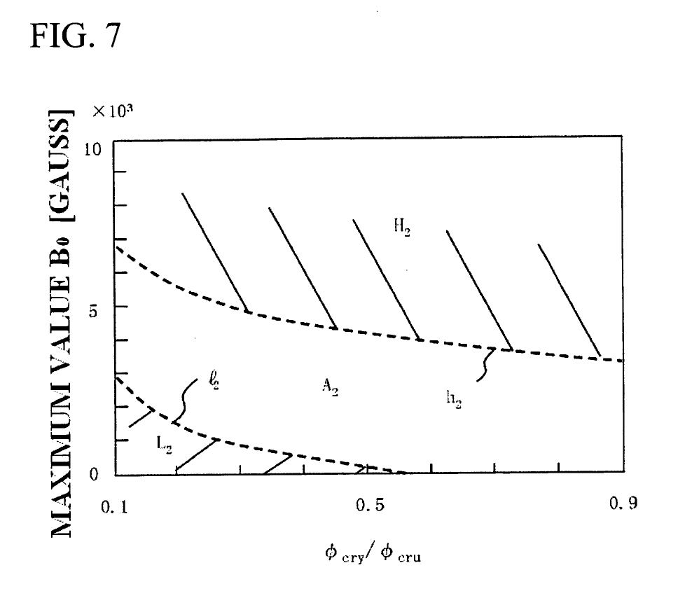

The formula (5) is explained below by referring to FIG. 7. FIG. 7 is a correlation diagram showing the relationship of the maximum value B₀ on cylindrical axis and (Φ_{cry}/Φ_{cru}). The vertical axis is the maximum value B₀ on cylindrical axis and the horizontal axis is a ratio of (Φ_{cry}/Φ_{cru}). In this case, the II-type horizontal magnetic field is generated by the saddle-shaped exciting coils.

In FIG. 7, a region H₂ indicates a condition which may cause crystal deformation, similar to FIG. 6. A broken line h₂ is the lower limit curve of the region H₂, and is obtained by numeric analysis using analysis program of solid-solution interface-linked three-dimensional convection flow, oxygen analysis program and heat transfer analysis program. The broken line h₂ is satisfied with following formula (7).

B₀=2000/(Φcry/Φcru)^{1/2}+2000 (7)

In FIG. 7, similar to FIG. 6, a region L₂ indicates a condition which may cause oscillating flow of molten silicon, and a broken line l₂ is the upper limit curve of the region L₂, and is obtained by numeric analysis using analysis program of solid-solution interface-linked three-dimensional convection flow, oxygen analysis program and heat transfer analysis program. The broken line l₂ is satisfied with following formula (8).

B₀=2000/(Φcry/Φcru)^{1/2}−2000 (8)

As described above, the formula (3) shows an appropriate region A₂ (shown in FIG. 7) of a horizontal magnetic field on which crystal deformation is not generated and oscillating flow of molten silicon is not generated.

The optimization of the II-type horizontal magnetic field is preferably conducted such that the maximum value B₀ on cylindrical axis generated in the molten silicon 12 in the quartz crucible 11 by the exciting coils 13 and 14 is satisfied with following formula (4).

2000/(Φcry/Φcru)^{1/2}−1000≦B₀≦2000/(Φcry/Φcru)^{1/2}+1000 (4)

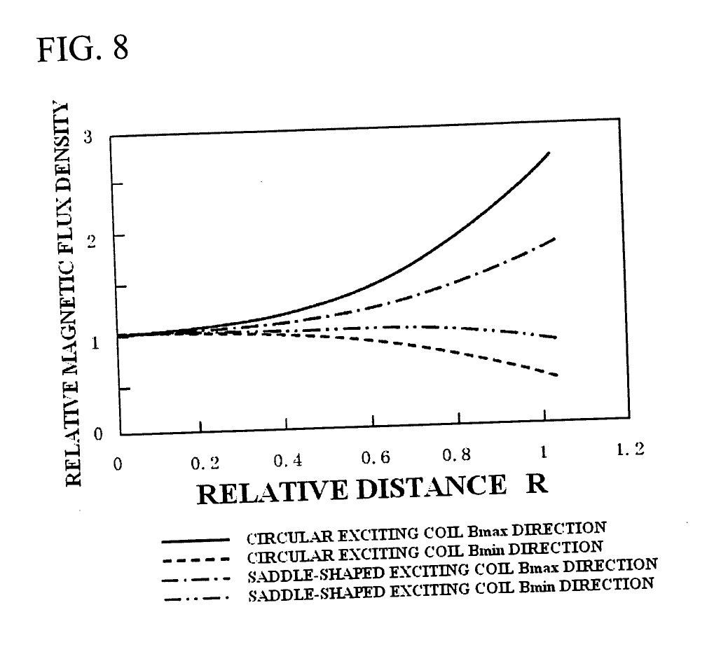

The fact that the optimization of horizontal magnetic field differs between the I-type horizontal magnetic field (for example, the case of circular exciting oils) and the II-type horizontal magnetic field (for example, the case of saddle-shaped exciting coils) is briefly described below. In general, in distribution of magnetic flux density on the horizontal symmetric plane 18, the I-type horizontal magnetic field shows larger deviations in distribution of horizontal magnetic field as compared with the II-type horizontal magnetic field. FIG. 8 is a distribution view of magnetic flux density showing one example of deviation in a radial direction from the cylindrical axis of the quartz crucible on the horizontal symmetric plane 18. The vertical axis is magnetic flux density in the cylindrical axis, that is, a relative magnetic flux axis standardized by the maximum value B₀ on cylindrical axis, and the horizontal axis is a relative distance standardized by a half of an inner diameter of a quartz crucible.

The relative magnetic flux density in the case of circular exciting coils is greatly increased together with a relative distance R in a direction of the maximum value Bₘₐₓ as shown by a solid line in FIG. 8, and the maximum value Bₘₐₓ at R=1 is about 2.67 times of the maximum value B₀ on cylindrical axis.

On the other hand, the relative magnetic flux density is greatly decreased together with the relative distance R in a direction of the minimum value Bₘᵢₙ on circle as shown by a broken line in FIG. 8, and the minimum value Bₘᵢₙ at R=1 is 0.498 times of the maximum value B₀ on cylindrical axis.

Thus, the I-type horizontal magnetic field (for example, the case of circular exciting oils) shows the deviation of magnetic flux density of 5 times between the maximum value and the minimum value of the horizontal magnetic field in the quartz crucible 11 (0.498 B₀ to 2.67B₀).

In contrast, the relative magnetic flux density of the II-type horizontal magnetic field (for example, the case of saddle-shaped exciting coils) is increased together with the relative distance R in a direction of the maximum value Bₘₐₓ as shown by a dashed-dotted line in FIG. 8. However, the degree of increase is small and the maximum value Bₘₐₓ at R=1 is about 1.73 times of B₀. On the other hand, the relative magnetic flux density is slightly decreased together with the relative distance R in a direction of the minimum value Bₘᵢₙ as shown by a two dashed-two dotted line in FIG. 8, and the minimum value Bₘᵢₙ at R=1 is 0.988 times of B₀. Thus, the II-type horizontal magnetic field shows the deviation of magnetic flux density of about 1.75 times between the maximum value and the minimum value of the horizontal magnetic field in the quartz crucible 11 (0.988B₀ to 1.73B₀).

Thus, the I-type horizontal magnetic field shows larger deviations in distribution of horizontal magnetic field as compared with the II-type horizontal magnetic field. Therefore, the magnetic flux density B₀ on axis is required to increase for suppressing the oscillating flow of molten silicon.

Here, where the deviation of magnetic flux density in a radial direction is increased, periodic oscillating flow of molten silicon such as pulsating flow and side flow are easily generated, and where the deviation of magnetic flux density on the circle is increased, periodic oscillating flow such as heterogeneous rotating flow, of molten silicon is easily generated.

The effects of the present exemplary embodiment are specifically described by showing the results of numeric analysis using analysis program of solid-solution interface-linked three-dimensional convection flow, oxygen analysis program and heat transfer analysis program, as described before. In this exemplary embodiment, the horizontal magnetic field was generated by saddle-shaped exciting coils. In the growth by pulling out of silicon single crystal, the quartz crucible 11 had an inner diameter of 900 mm (about 36 inches), residual amount of the molten silicon 12 was 300 kg, a diameter of a straight body part of the silicon single crystal 15 was 450 mm (about 18 inches), and its length was 800 mm. The pulling out conditions were that pulling out rate is 0.8 mm/min, rotation rate of a quartz crucible is 1 rpm, rotation rate of silicon single crystal is 5 rpm, and the horizontal symmetric plane 18 is liquid level of the molten silicon 12.

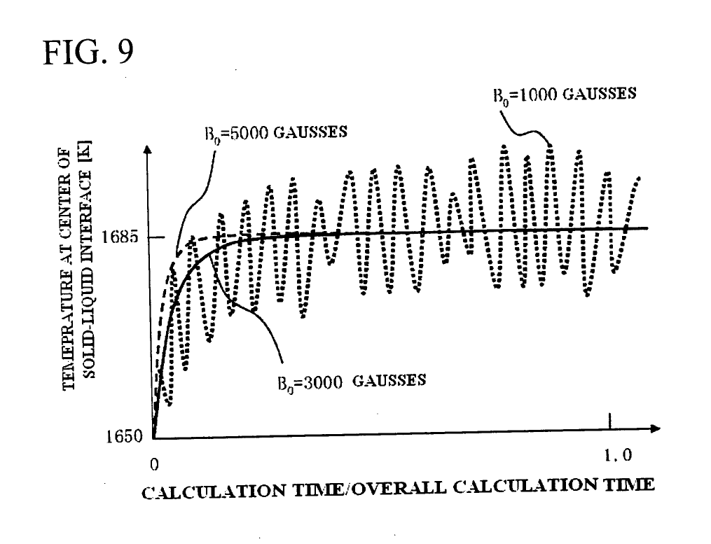

FIG. 9 is a graph showing one example of suppression effect to the oscillating flow of molten silicon. In FIG. 9, the vertical axis is temperature of molten silicon at a center of the solid-liquid interface 15a calculated by the numeric analysis, and the horizontal line is lapse time in dimensionless numeric analysis. Convection flow of molten silicon in the lower region of the solid-liquid interface 15a easily becomes a state of turbulent flow when the maximum value B₀ on cylindrical axis is 1,000 gausses. Furthermore, the oscillating flow of molten silicon easily develops, and as a result, the temperature of molten silicon at the center of the solid-liquid interface 15a temporally fluctuates up and down to, for example, the melting point (1,685K) as shown in FIG. 9. In contrast, when the maximum value B₀ on cylindrical axis is increased to, for example, 3,000 to 5,000 gausses, the oscillating flow of molten silicon is effectively suppressed, the temperature of molten silicon is stabilized in a short period of time, and temporal fluctuation does not occur.

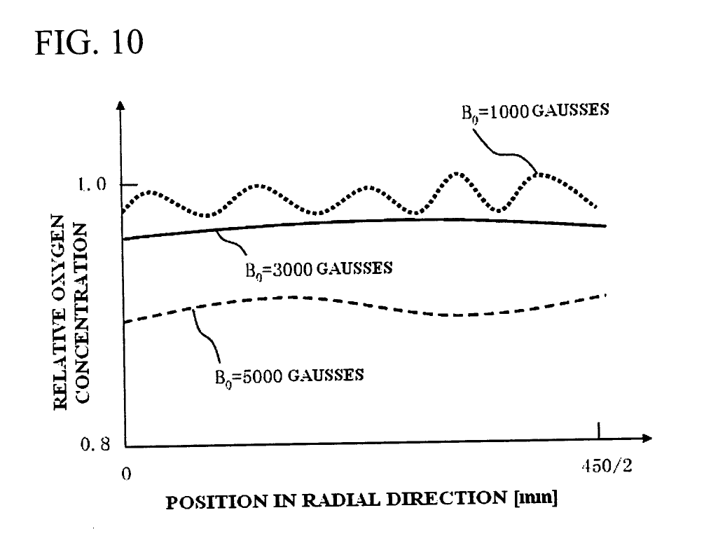

As shown in FIG. 10, distribution in a radial direction of oxygen concentration in the silicon single crystal 15 is homogenized by the suppression effect of the oscillating flow of molten silicon. FIG. 10 is a graph showing one example of homogenization effect of oxygen concentration distribution. The vertical axis is a relative oxygen concentration in silicon single crystal calculated by the numeric analysis, and the horizontal line is a position in radial direction of silicon single crystal.

It is read that when the maximum value B₀ on cylindrical axis is 1,000 gausses, the oxygen concentration in silicon single crystal periodically fluctuates in a radial direction. In contrast, when the maximum value B₀ on cylindrical axis is increased to, for example, 3,000 to 5,000 gausses, the fluctuation of oxygen concentration does not occur. Furthermore, as well known, oxygen concentration level is decreased with the increase in intensity of the magnetic field.

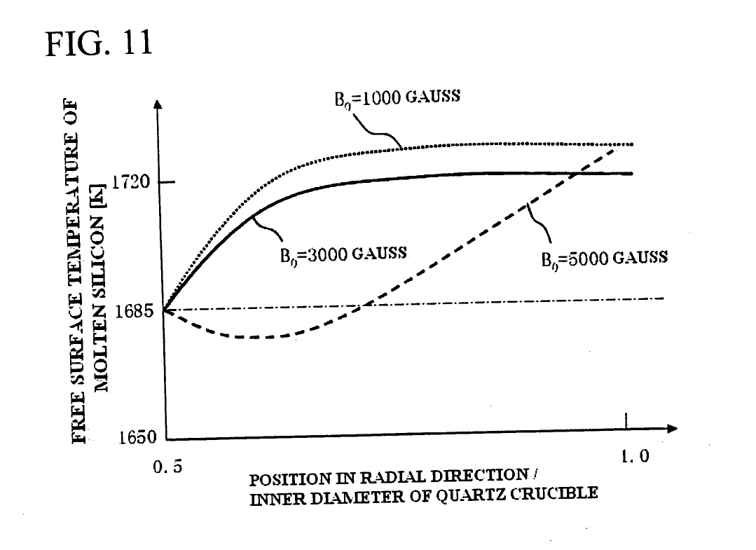

FIG. 11 is a graph showing one example of free surface temperature of molten silicon used to explain the suppression effect of crystal deformation. In FIG. 11, the vertical axis is a temperature of free surface of the molten silicon 12 calculated by the numeric analysis, and the horizontal axis is a position in a radial direction of quartz crucible, which is standardized by its inner diameter and is shown from the edge of the solid-liquid interface 15a.

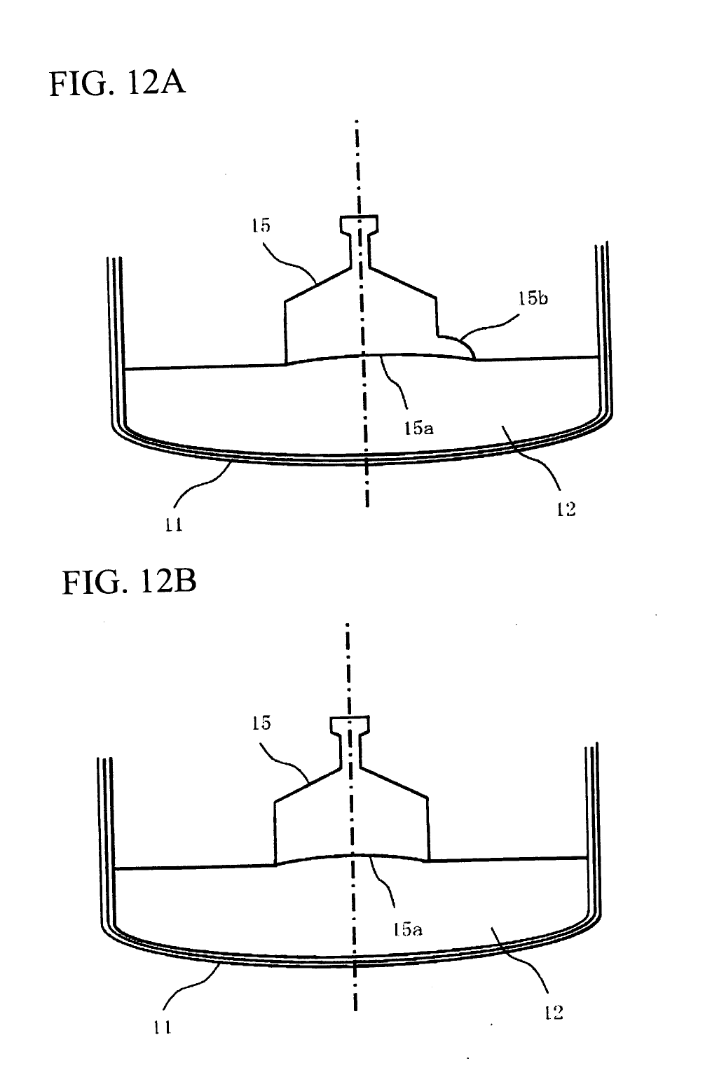

It is read that when the maximum value B₀ on cylindrical axis is 5,000 gausses, the surface temperature of molten silicon is once decreased lower than the melting point (1,685K) in a radial direction from the edge of the solid-liquid interface 15a, and then gradually increased. For this reason, meniscus of molten silicon on the circle of the silicon single crystal 15 becomes instable, and is easily solidified, and as a result, a crystal deformation part 15b periodically develops, as shown in FIG. 12A.

In contrast, where the maximum value B₀ on cylindrical axis is decreased to, for example, 3,000 gausses from 5,000 gausses, the surface temperature of molten silicon is monotonically increased in a radial direction from the edge of the solid-liquid interface 15a. Meniscus of molten silicon on the circle of the silicon single crystal 15 becomes extremely stable, and crystal deformation does not occur, as shown in FIG. 12B.

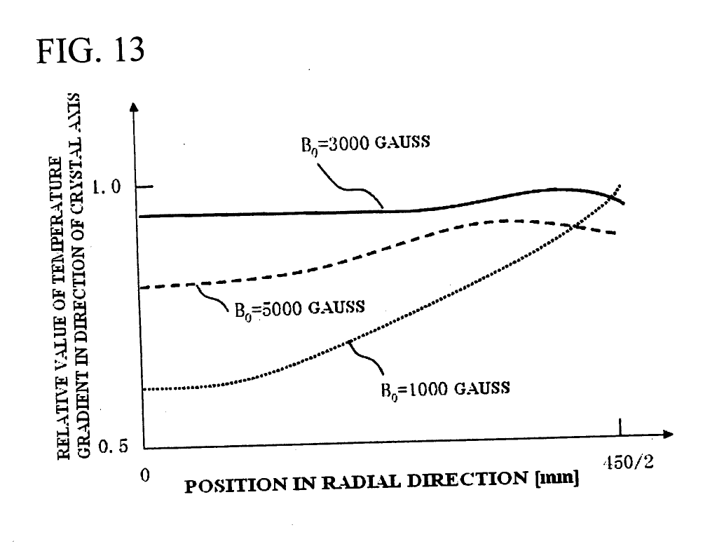

FIG. 13 is a graph showing one example of homogenization effect of G (temperature gradient in a direction of crystal axis) in the solid-liquid interface. In FIG. 13, the vertical axis is a relative value of temperature gradient in a direction of crystal axis, which is a relative value of the G, and the horizontal axis is a position in a radial direction of silicon single crystal.

It is read that when the maximum value B₀ on cylindrical axis is 3,000 gausses, the relative value of temperature gradient in a direction of crystal axis is homogenized in a radial direction. On the other hand, it is read that when the maximum value B₀ on cylindrical axis is 1,000 gausses which is weak magnetic field, the maximum value B₀ is greatly decreased at the center of crystal, and becomes heterogeneous. It is further read that even when the maximum value B₀ on cylindrical axis is, for example, 5,000 gausses which is strong magnetic field, the maximum value B₀ is decreased at the center of crystal, and becomes heterogeneous than the case that the maximum value B₀ on cylindrical axis is 3,000 gausses.

Homogenization of the G in a radial direction makes it extremely easy to control a so-called V (pulling out rate)/G (temperature gradient in a direction of crystal axis) ratio and control a shape of the solid-liquid interface. Furthermore, control to reduce crystal defects due to point defects in the silicon single crystal is remarkably improved, and additionally, practical application of defect-free crystal becomes easy.

The effect of appropriate setting of the maximum value B₀ on cylindrical axis of the magnetic flux density is mainly caused from appropriate control of upward flow of molten silicon at the lower part of a solid-liquid interface and temperature control of the molten silicon due to the control of upward flow. Those controls become extremely easy when the cylindrical axis of the quartz crucible 11 as explained in FIG. 1 is nearly consistent with a central axis of pulling out of silicon single crystal. However, those controls are easy even when the cylindrical axis is not consistent with the central axis of pulling out.

Owing to the above described controls, in addition to the above effects, obtained effects are reduction of dislocation of pulling out single crystal; improvement in oxygen concentration in a radial direction in silicon single crystal, a dopant, and in-plane homogeneity such as crystal defects; stabilization of crystal growth.

Although the details are described hereinafter, many pulling out conditions such as pulling out rate, rotation rate of a quartz crucible and silicon single crystal, position of molten silicon on a horizontal symmetric plane, heater output, position of a radiation shield, and flow rate of an inert gas such as argon introduced into a growth furnace are adjusted in the growth by pulling out of silicon single crystal. However, where the silicon single crystal has a diameter exceeding, for example, 300 mm, the above-described optimization of magnetic field is most effective in growing a high grade crystal by pulling out.

In the present exemplary embodiment, guidelines for designing appropriate magnetic field are obtained in the growth of silicon single crystal by MCZ method applying horizontal magnetic field, and it becomes possible to apply appropriate magnetic field to molten silicon. In the case that a size of a quartz crucible is changed according to a length or a diameter of silicon single crystal, a range of horizontal magnetic field suitable for a size of a quartz crucible can be determined. Furthermore, the present exemplary embodiment is extremely useful in designing magnetic field of an apparatus for producing next generation of silicon single crystal or silicon single crystal next-next generation, having a larger diameter. This can avoid increase in facilities for generating magnetic field, making it possible to design appropriate facilities having excellent economical efficiency.

In the present exemplary embodiment, horizontal magnetic field generated by the exciting coils 13 and 14 may be that the horizontal symmetric plane 18 is not formed. In the horizontal symmetric plane 18, magnetic flux density is face-symmetric upper and lower the horizontal plane, but the horizontal plane may not be symmetric plane of magnetic flux density. Furthermore, the bottomed cylindrical quartz crucible 11 is preferably that its cross section is nearly perfect circle shape, but the circle may slightly get distorted. For example, the circle may slightly get distorted like elliptical shape.

### Second Exemplary Embodiment

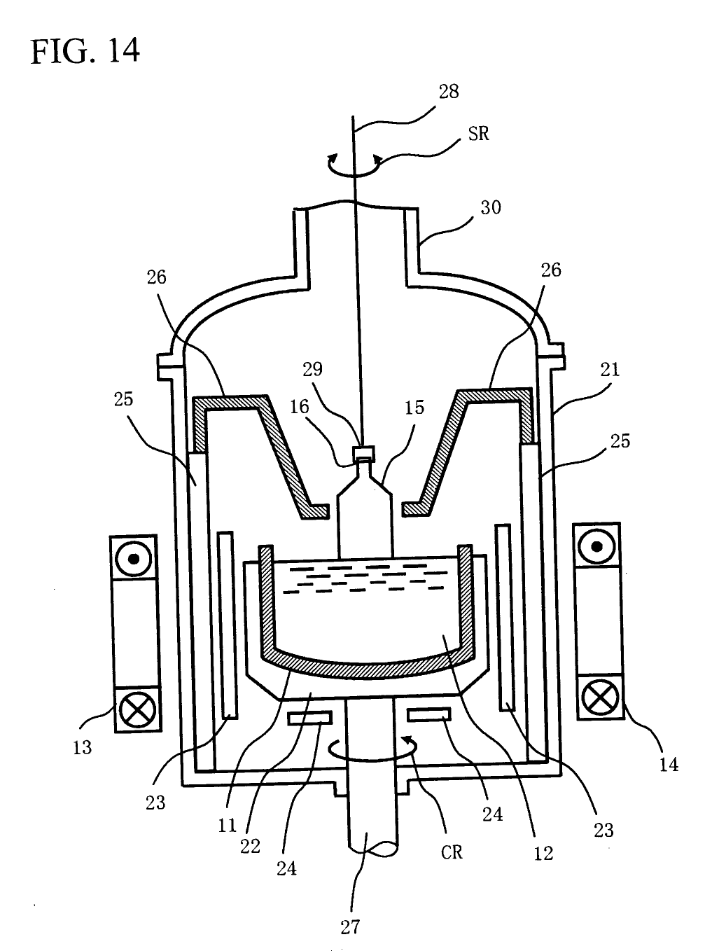

A manufacturing method of silicon single crystal according to a second exemplary embodiment of the present invention is described below by referring to FIG. 14.

The manufacturing apparatus of silicon single crystal has a bottomed cylindrical main chamber 21. In the main chamber 21, a quartz crucible 11 adapted to filled with molten silicon 12 and a graphite crucible 22 arranged on outside of the quartz crucible 11 are provided in a form of a double structure. Further, the manufacturing apparatus has side heaters 23 and bottom heaters 24 for heating the graphite crucible 22 with a given distance to the graphite crucible 22. Further, heat-insulting members 25 are arranged at a position outside the side heaters 23 and the bottom heaters 24 and between those heaters and the main chamber 21. Furthermore, radiant shields 26 having, for example, a cut conical shape, for shielding heat of radiation from the side heaters 23 to silicon single crystal 15 is arranged at the upper edge of the heat-insulating member 25 so as to freely move upward and downward.

A pair of exciting coils 13 and 14 for generating horizontal magnetic field, which generate horizontal magnetic field in the molten silicon 12 are arranged outside the main chamber 21 so as to face with each other. The horizontal magnetic field is appropriately set according to a diameter of a straight body part of the silicon single crystal 15 and a size of the quartz crucible 15, as described hereinafter.

A supporting shaft 27 for rotating and lifting the quartz crucible 11 and the graphite crucible 22 is provided, and the supporting shaft 27 is rotatably controlled by a rotation/lifting apparatus (not shown). The supporting shaft 27 rotates the graphite crucible 22 and the quartz crucible 11 such that a direction of pulling out of the silicon single crystal (direction of crystal axis) is a rotational axis, and further moves those crucibles upward/downward so as to adjust the level of the molten silicon 12 so that the magnetic field is applied to a desired area of the molten silicon. A space between the supporting shaft 27 and the main chamber 21 is tightly sealed with a sealing member (not shown).

A pulling out shaft 28 having a wire is connected to a seed chuck 29 which holds a seed crystal 16 at the upper part of a neck of the silicon single crystal 15. The pulling out shaft hangs down in the main chamber 21 from a pull chamber 30 and pulls out the silicon single crystal in a given rate.

The manufacturing apparatus is appropriately provided with an exhaust port (not shown) for discharging an inert gas such as argon outside the chamber at the bottom of the main chamber 21, for example. The silicon single crystal 15 may be provided with a mechanism or member for adding effective impurities such as boron, arsenic and phosphorus, but those are omitted for the sake of simplifying the explanation of the present invention.

An exemplary embodiment of manufacturing silicon single crystal using the manufacturing apparatus of silicon single crystal is described below. The quartz crucible 11 is filled with raw material silicon containing polycrystalline silicon and an appropriate amount of effective impurities as additives. An inert gas such as argon gas is flown in the main chamber 21, the raw material silicon is melted in the inert gas atmosphere, and the molten silicon 12 is formed in the quartz crucible 11. The inert gas is rectified on the surface of the molten silicon 12, and SiO as a volatile from the liquid level is effectively discharged outside the growth furnace.

The seed crystal 16 held by the seed chuck 29 is placed on the molten silicon 12. The pulling out shaft 28 is moved upward while rotating in one direction. Simultaneously, rotating the quartz crucible 11 in one direction (rotation CR is given to the quartz crucible 11) and rotating the pulling out shaft 28 in the same or reverse direction (rotation SR is given to the shaft 28) to thereby grow the silicon single crystal 15 having the neck portion to the tail portion as described before. In the growth by pulling out, the horizontal magnetic field generated by the exciting coils 13 and 14 may be applied to the molten silicon 12 from the necking process, or as the case may be, the horizontal magnetic field may be applied from the shoulder part forming process which enlarges its diameter.

In the above described manufacturing of the silicon single crystal, magnetic field applied to the molten silicon 11 is set by the optimization method of horizontal magnetic field in pulling out silicon single crystal as described in the first exemplary embodiment, and the silicon single crystal having a diameter of a straight body part exceeding 300 mm is pulled up and grown. Specifically, appropriate horizontal magnetic field is applied to the molten silicon 12 from the exciting coils 13 and 14 by taking into consideration of target diameter of the obtaining silicon single crystal 15 and a size of the quartz crucible 11.

Other pulling out conditions such as pulling out rate, rotation rate of of the quartz crucible 11, rotation rate of the silicon single crystal 15, position of the horizontal symmetric plane 18, output of the side heaters 23 and the bottom heaters 24, position of the radiant shield 26, and flow rate of an inert gas such as argon introduced into a growth furnace are appropriately adjusted in the growth by pulling out.

For example, in the I-type horizontal magnetic field (for example, a case of circular exciting coils) and when a target diameter of a straight body part of the silicon single crystal 15 is 450 mm (about 18 inches),

(1-1) when the inner diameter of the quartz crucible 11 is 900 mm (about 36 inches), the maximum value B₀ on cylindrical axis on the cylindrical axis of the quartz crucible 11 is set in a range from 1,000 gausses to 5,000 gausses, and preferably from a range from 2,000 gausses to 4,000 gausses;

(1-2) when the inner diameter of the quartz crucible 11 is 1,200 mm (about 48 inches), the maximum value B₀ is set in a range from 2,000 gausses to 6,000 gausses, and preferably a range from 3,000 gausses to 5,000 gausses; and

(1-3) when the inner diameter of the quartz crucible 11 is 1,350 mm (about 54 inches), the maximum value B₀ is set in a range from 2,500 gausses to 6,500 gausses, and preferably a range from 3,500 gausses to 5,500 gausses.

Alternatively, in the I-type horizontal magnetic field and when the target diameter of a straight body part of the silicon single crystal 15 is 675 mm (about 27 inches),

(1-4) when the inner diameter of the quartz crucible 11 is 1,350 mm (about 54 inches), the maximum value B₀ on cylindrical axis on the cylindrical axis of the quartz crucible 11 is set in a range from 1,000 gausses to 5,000 gausses, and preferably a range from 2,000 gausses to 4,000 gausses;

(1-5) when the inner diameter of the quartz crucible 11 is 1,800 mm (about 72 inches), the maximum value B₀ is a range from 2,000 gausses to 6,000 gausses, and preferably a range from 3,000 gausses to 5,000 gausses; and

(1-6) when the inner diameter of the quartz crucible 11 is 2,025 mm (about 81 inches), the maximum value B₀ is set in a range from 2,500 gausses to 6,500 gausses, and preferably a range from 3,500 gausses to 5,500 gausses.

In the II-type horizontal magnetic field (for example, a case of saddle-shaped exciting coils) and when the target diameter of the straight body part of the silicon single crystal 15 is 450 mm (about 18 inches),

(2-1) when the inner diameter of the quartz crucible 11 is 900 mm (about 36 inches), the maximum value B₀ on cylindrical axis on the cylindrical axis of the quartz crucible 11 is set in a range from 800 gausses to 4,800 gausses, and preferably a range from 1,800 gausses to 3,800 gausses;

(2-2) when the inner diameter of the quartz crucible 11 is 1,200 mm (about 48 inches), the maximum value B₀ is set in a range from 1,300 gausses to 5,300 gausses, and preferably a range from 2,300 gausses to 4,300 gausses; and

(2-3) when the inner diameter of the quartz crucible 11 is 1,350 mm (about 54 inches), the maximum value B₀ is set in a range from 1,500 gausses to 5,500 gausses, and preferably a range from 2,500 gausses to 4,500 gausses.

Furthermore, in the II-type horizontal magnetic field and when the target diameter of the straight body part of the silicon single crystal 15 is 675 mm (about 27 inches),

(2-4) when the inner diameter of the quartz crucible 11 is 1,350 mm (about 54 inches), the maximum value B₀ on cylindrical axis on the cylindrical axis of the quartz crucible 11 is set in a range from 800 gausses to 4,800 gausses, and preferably a range from 1,800 gausses to 3,800 gausses;

(2-5) when the inner diameter of the quartz crucible 11 is 1,800 mm (about 72 inches), the maximum value B₀ is set a range from 1,300 gausses to 5,300 gausses, and preferably a range from 2,300 gausses to 4,300 gausses; and

(2-6) when the inner diameter of the quartz crucible 11 is 2,025 mm (about 81 inches), the maximum value B₀ is set in a range from 1,500 gausses to 5,500 gausses, and preferably a range from 2,500 gausses to 4,500 gausses.

The same effect as described in the first exemplary embodiment is exhibited in manufacturing the silicon single crystal according to the present exemplary embodiment. In the growth by pulling out of silicon single crystal having a large diameter exceeding 300 mm, stabilized and high precision pulling out conditions are easily secured, and growth of high grade crystal becomes possible. Furthermore, facilities for generation of magnetic field are not greatly increased, thereby reducing production cost of silicon single crystal.

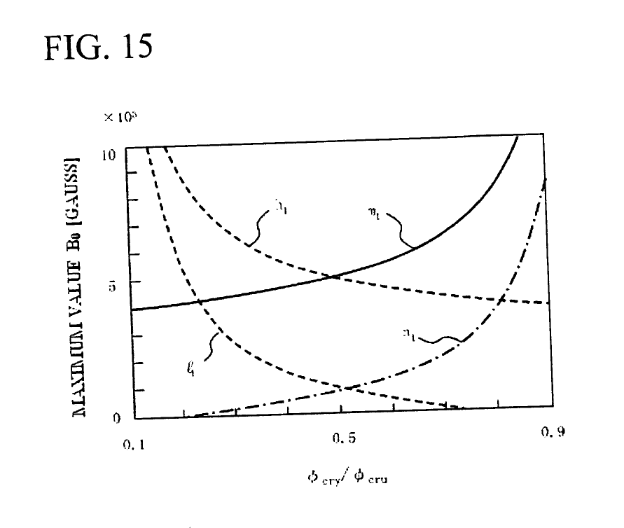

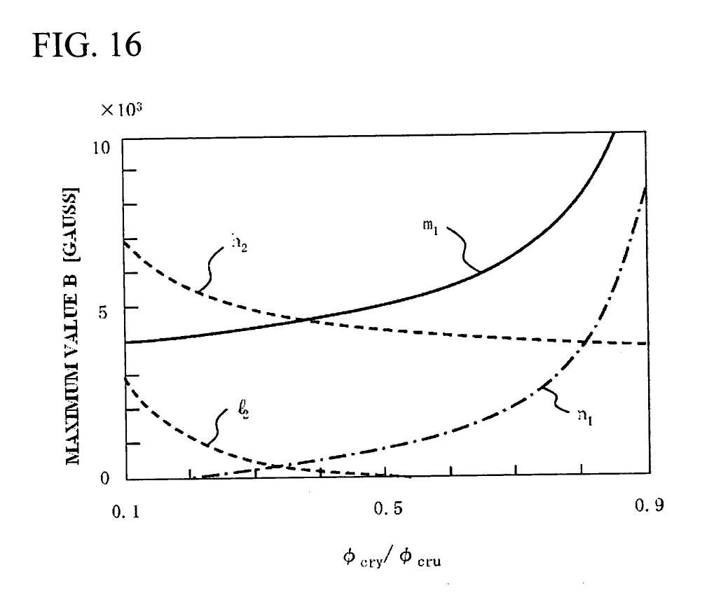

In manufacturing the silicon single crystal, the correlation between the maximum value B₀ on cylindrical axis and Φ_{cry}/Φ_{cru}, and correlation between oxygen concentration in silicon single crystal and Φ_{cry}/Φ_{cru} can numerically be analyzed by the oxygen analysis program in the first exemplary embodiment, and can be predicted. The results of the numeric analysis are shown in FIGS. 15 and 16. FIG. 15 is the case of the I-type horizontal magnetic field using, for example, the circular exciting coils 131 and 141, as same as in FIG. 6. FIG. 16 is the case of the II-type horizontal magnetic field using, for example, the saddle-shaped exciting coils 132 and 142, as same as in FIG. 7. In FIGS. 15 and 16, a solid line m₁ is the lower limit curve of oxygenation at extremely low concentration (7×10¹⁷ atoms/cm³ or less) and a dashed-dotted line n₁ is the upper limit curve of oxygenation at extremely low concentration (15×10¹⁷ atoms/cm³ or more). In those graphs, an isoconcentration curve of oxygen is present between the lower limit curve and the upper limit curve, and the maximum value B₀ on cylindrical axis is monotonically increased with the increase of Φ_{cry}/Φ_{cru}.

It is read from FIG. 15 and FIG. 16 that the increase of Φ_{cry}/Φ_{cru} is effective in the case that a necessary oxygen concentration in the silicon single crystal 15 is increased. On the other hand, it is read that the decrease of Φ_{cry}/Φ_{cru} is effective in the case that a necessary oxygen concentration in the silicon single crystal 15 is decreased. Specifically, in the case that oxygen concentration in the silicon single crystal 15 is increased and silicon single crystal is grown by pulling out, an inner diameter of the quartz crucible 11 is decreased. On the other hand, in the case that oxygen concentration in the silicon single crystal 15 is decreased and silicon single crystal is grown by pulling out, an inner diameter of the quartz crucible 11 is increased. The control of the quartz crucible 11 is effectively applied to the production of next generation of silicon single crystal and silicon single crystal after next generation, having an increased diameter.

The control of the quartz crucible 11 permits to decrease width of increase and decrease of magnetic field in the adjustment of magnetic field intensity for obtaining the desired oxygen concentration. Furthermore, facilities for the generation of magnetic field can be simplified, and production cost of silicon single crystal is reduced.

Although the present invention has been described by reference to the preferred exemplary embodiments, the above exemplary embodiments do not limit the present invention. One skilled in the art can make various modifications or changes in the specific exemplary embodiments without departing technical concept and technical scope of the present invention.

The above exemplary embodiments describe the case of the growth by pulling out of silicon single crystal, but the present invention can similarly be applied to the growth by pulling out of semiconductor single crystals of III-V series and II-VI compounds in the periodic table.

The present invention is particularly effective to the case of the growth of silicon single crystal having a large diameter exceeding 300 mm which will be mainly required aftertime, but can quite similarly be applied to the case of the growth of the conventional silicon single crystal having a diameter of 300 mm or less.

What is claimed is:

1. A manufacturing method of silicon single crystal, comprising:
pulling out a silicon single crystal from melt silicon stored in a cylindrical crucible by Czochralski method while applying horizontal magnetic field satisfying formulas of
2000/(Φcry/Φcru)^{1/2}−2000≦B₀≦2000/(Φcry/Φcru)^{1/2}+2000 and
0.8B_{0≦B}ₘᵢₙ or 0.6Bₘₐₓ≦Bₘᵢₙ
wherein B₀ [gauss] is a maximum value of a magnetic flux density on an cylindrical axis of the crucible,
Bₘᵢₙ [gauss] is a minimum value of the magnetic flux density on a circle where an inner diameter of the crucible intersects with a horizontal plane which crosses a point of which magnetic flux density is B₀ and is perpendicular to the cylindrical axis of the crucible,
Bₘₐₓ [gauss] is a maximum value of the magnetic flux density on the circle,
Φ_{cry} is a diameter of a straight body part of the silicon single crystal,
Φ_{cru} is an inner diameter of the crucible, and
the horizontal magnetic field is applied by a pair of exciting coils disposed on both side portions of the crucible.

2. The manufacturing method of the silicon single crystal as set forth in claim 1,
wherein B₀ satisfying
2000/(Φcry/Φcru)^{1/2}−1000≦B₀≦2000/(Φcry/Φcru)^{1/2}+1000 .

3. The manufacturing method of the silicon single crystal as set forth in claim 1, wherein the exciting coil is a saddle-shaped coil.

4. The manufacturing method of the silicon single crystal as set forth in claim 1, wherein a ratio of Φ_{cry}/Φ_{cru} is set larger as a required oxygen concentration in the silicon single crystal is higher.

5. A manufacturing method of a silicon single crystal comprising:
pulling out a silicon single crystal from melt silicon stored in a cylindrical crucible by Czochralski method while applying horizontal magnetic field satisfying formulas of
1500/(Φcry/Φcru)−2000≦B₀≦1500/(Φcry/Φcru)+2000 and
Bₘᵢₙ≦0.9B₀ or Bₘᵢₙ≦0.65Bₘₐₓ
wherein B₀ [gauss] is a maximum value of a magnetic flux density on an cylindrical axis of the crucible,
Bₘᵢₙ [gauss] is a minimum value of the magnetic flux density on a circle where an inner diameter of the crucible intersects with a horizontal plane which crosses a point of which magnetic flux density is B₀ and is perpendicular to the cylindrical axis of the crucible,
Bₘₐₓ [gauss] is a maximum value of the magnetic flux density on the circle,
Φcry is a diameter of a straight body part of the silicon single crystal,
Φcru is an inner diameter of the crucible, and
the horizontal magnetic field is applied by a pair of exciting coils disposed on both side portions of the crucible.

6. The manufacturing method of the silicon single crystal as set forth in claim 5,
wherein B₀ satisfying
1500(Φcry/Φcru)−1000≦B₀≦1500/(Φcry/Φcru)+1000.

7. The manufacturing method of the silicon single crystal as set forth in claim 5, wherein the exciting coil is a circular coil.

8. The manufacturing method of the silicon single crystal as set forth in claim 5, wherein a ratio of Φ_{cry}/Φ_{cru} is set larger as a required oxygen concentration in the silicon single crystal is higher.
